(19) United States
(12) Patent Application Publication
(10) Pub. No.: US 2006/0011912 A1
(43) Pub. Date: Jan. 19, 2006

(54) Method of forming a metal pattern and a method of fabricating tft array panel by using the same

(75) Inventors: Hong-Sick Park, Kyungki-do (KR); Sung-Chul Kang, Kyungki-do (KR); Hong-Je Cho, Kyungki-do (KR); An-Na Park, Busan-city (KR); Pong-ok Park, Kwanak-ku (KR); Chang-Oh Jeong, Kyungki-do (KR)

Correspondence Address: MCGUIREWOODS, LLP, 1750 TYSONS BLVD, SUITE 1800, MCLEAN, VA, 22102, US

(73) Assignee: Samsung Electronics Co

(21) Appl. No.: 10/516,602

(22) PCT Filed: Jul. 24, 2002
(86) PCT No.: PCT/KR02/01391

§ 371 Date: Jul. 5, 2005

(30) Foreign Application Priority Data
Jun. 12, 2002 (KR) 200232884

(51) Int. Cl. H01L 29/04

(52) U.S. Cl. 257/59

(57) ABSTRACT

With a metal pattern formation process and a method of manufacturing a thin film transistor array panel using the metal pattern formation process, an organometallic layer is formed by coating an organometallic complex containing metal. The organometallic layer is exposed to light through a photo mask, and developed to form a metal pattern.

### BACKGROUND OF THE INVENTION

(a) Field of the Invention

The present invention relates to a metal pattern formation process, and a method of manufacturing a thin film transistor array panel using the same.

(b) Description of the Related Art

Generally, a thin film transistor (“TFT”) array panel for a liquid crystal display (“LCD”) or an electro-luminescence (“EL”) display is used as a circuit board for driving the respective pixels in an independent manner. The TFT array panel includes a scanning signal wire or a gate wire transmitting scanning signals, an image signal wire or a data wire transmitting image signals, TFTs connected to the gate and the data wire, pixel electrodes connected to the TFTs, a gate insulating layer covering the gate wire for insulation, and a protective layer covering the TFTs and the data wire for insulation.

The TFT is a switching element for transmitting the image signals from the data wire to the pixel electrode in response to the scanning signals from the gate wire.

In the TFT array panels, the gate wire includes gate lines, gate electrodes and gate pads, and the data wire includes data lines, data electrodes, data pads, and source/drain electrodes. The gate wire and the data wire are made of a metallic material such as Ta, Al and Mo. Furthermore, a reflective electrode is also made of a metallic material exhibiting excellent light reflection characteristic, such as Al.

In order to form a signal wire or a reflective electrode using the metallic material, a photolithography process with the steps of depositing a metallic layer, coating a photoresist film on the metallic layer, exposing the photoresist film to light by way of a photo mask, developing the light-exposed photoresist film and etching the metallic layer using the developed photoresist film as a mask should be introduced. However, the photolithography process is a very complex and high cost process, which is a critical factor in the production cost and time for the TFT array panel. Therefore, in order to reduce the production cost for the TFT array panel while enhancing the productivity thereof, the number of processing steps related to the photolithography process should be reduced.

### SUMMARY OF THE INVENTION

It is an object of the present invention to simplify the steps of forming a metal pattern.

It is another object of the present invention to simplify the steps of manufacturing a thin film transistor array panel.

These and other objects may be achieved by a process where a metallic wire is formed by coating a photosensitive organometallic complex, exposing the coated organometallic layer to light, and developing the light-exposed organometallic layer.

Specifically, in the metal pattern formation process, an organometallic layer is formed by coating a photosensitive organometallic complex. The organometallic layer is exposed to light through a photo mask. A metal pattern is formed by developing the organometallic layer.

The development of the organometallic layer is made by way of an organic solvent, and the light-blocking pattern of the photo mask is positioned at the area external to the area to be made of the metal pattern.

According to one aspect of the present invention, in a method of manufacturing a thin film transistor array panel, a gate wire is formed on an insulating substrate. The gate wire has gate lines, gate electrodes and gate pads. A gate insulating layer, an amorphous silicon layer and an ohmic contact layer are sequentially deposited on the gate wire. The ohmic contact layer and the amorphous silicon layer are patterned by photolithography. A data wire is formed on the ohmic contact layer. The data wire has source and drain electrodes, data lines and data pads. A protective layer is formed on the data wire. The protective layer has a first contact hole exposing the drain electrode, a second contact hole exposing the gate pad and a third contact hole exposing the data pad. A pixel electrode, a subsidiary gate pad and a subsidiary data pad are formed on the protective layer. The pixel electrode is connected to the drain electrode through the first contact hole. The subsidiary gate pad is connected to the gate pad through the second contact hole. The subsidiary data pad is connected to the data pad through the third contact hole. At least one of the steps of forming the gate wire, the data wire and the pixel electrode comprises the sub-steps of forming an organometallic layer by coating a photosensitive organometallic complex, placing a photo mask over the organometallic layer such that a predetermined region of the organometallic layer is exposed to the outside, exposing the organometallic layer to light through the photo mask, and developing the organometallic layer.

According to another aspect of the present invention, in a method of manufacturing a thin film transistor array panel, a gate wire is formed on an insulating substrate. The gate wire has gate lines, gate electrodes and gate pads. A gate insulating layer, an amorphous silicon layer, an ohmic contact layer and a metallic layer are sequentially deposited on the gate wire. The metallic layer, the ohmic contact layer and the amorphous silicon layer are patterned by photolithography to form a data wire and channel portions. The data wire has source and drain electrodes, data lines and data pads. Each channel portion is placed between the source and the drain electrodes. A protective layer is formed on the data wire with first to third contact holes. A pixel electrode, a subsidiary gate pad and a subsidiary data pad are formed on the protective layer. The pixel electrode is connected to the drain electrode through the first contact hole. The subsidiary gate pad is connected to the gate pad through the second contact hole. The subsidiary data pad is connected to the data pad through the third contact hole. At least one of the steps of forming the gate wire, the data wire and the pixel electrode comprises the sub-steps of forming an organometallic layer by coating a photosensitive organometallic complex, placing a photo mask over the organometallic layer such that a predetermined region of the organometallic layer is exposed to the outside, exposing the organometallic layer to light through the photo mask, and developing the organometallic layer.

The development of the organometallic layer is made by way of an organic solvent, and the light-blocking pattern of the photo mask is positioned at the area external to the area to be made of the signal wire or the pixel electrode. The metal is Ag, and the protective layer has a surface with prominent and depressed portions.

According to still another aspect of the present invention, a thin film transistor array panel includes an insulating substrate, a gate wire formed on the insulating substrate, and a gate insulating layer formed on the gate wire. A semiconductor layer is formed on the gate insulating layer. A data wire is formed on the semiconductor layer and the gate insulating layer. A protective layer is formed on the data wire. A pixel electrode is formed on the protective layer. At least one of the gate wire, the data wire and the pixel electrode is formed by way of a metal pattern formation process with the steps of forming an organometallic layer by coating a photosensitive organometallic complex, placing a photo mask over the organometallic layer such that a predetermined region of the organometallic layer is exposed to the outside, exposing the organometallic layer to light through the photo mask, and developing the organometallic layer.

The semiconductor layer includes an amorphous silicon layer and an ohmic contact layer. The ohmic contact layer has the same plane pattern as the data wire, and the amorphous silicon layer has the same plane pattern as the ohmic contact layer at the non-channel area.

According to still another aspect of the present invention, a thin film transistor array panel includes an insulating substrate, a gate wire formed on the insulating substrate, and a gate insulating layer formed on the gate wire. A data wire is formed on the gate insulating layer with a triple-layered structure of an amorphous silicon layer, an ohmic contact layer and a metallic layer. A protective layer is formed on the data wire. A pixel electrode is formed on the protective layer. At least one of the gate wire, the data wire and the pixel electrode is formed by way of a metal pattern formation process with the steps of forming an organometallic layer by coating a photosensitive organometallic complex, placing a photo mask over the organometallic layer such that a predetermined region of the organometallic layer is exposed to the outside, exposing the organometallic layer to light through the photo mask, and developing the organometallic layer.

The data wire has data lines, source electrodes connected to the data lines and drain electrodes facing the source electrodes, and a channel portion is formed between the source and the drain electrodes only with an amorphous silicon layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or the similar components, wherein:

FIG. 1 schematically illustrates a process of forming a metal pattern according to the present invention;

FIGS. 2A and 2B are SEM photographs of a surface of a metallic thin film and a section thereof, respectively;

FIG. 3 is an amplified photograph of the metallic thin film shown in FIG. 2B;

FIG. 4A is a plan view of a TFT array panel according to a first preferred embodiment of the present invention;

FIG. 4B is a cross sectional view of the TFT array panel taken along the IV-IV′ line of FIG. 4A;

FIGS. 5 to 11B sequentially illustrate the steps of manufacturing the TFT array panel shown in FIG. 4A;

FIG. 12A is a plan view of a TFT array panel according to a second preferred embodiment of the present invention;

FIG. 12B is a cross sectional view of the TFT array panel taken along the XIIb-XIIb′ line of FIG. 12A;

FIG. 12C is a cross sectional view of the TFT array panel taken along the XIIc-XIIc′ line of FIG. 12A; and

FIGS. 13A to 19C sequentially illustrate the steps of manufacturing the TFT array panel shown in FIG. 12A.

### DESCRIPTION OF THE REFERENCE NUMERALS

95: Subsidiary gate pad, 97: Subsidiary data pad

110: Insulating substrate, 121: Gate line

123: Gate electrode, 125: Gate pad

131: Storage electrode line, 140: Gate insulating layer

151, 153, 157,159: Semiconductor layer, 161, 163, 165: Ohmic contact layer

171: Data line, 173: Source electrode

175: Drain electrode, 177: Storage capacitor electrode

179: Data pad, 190: Pixel electrode

### DETAILED DESCRIPTION OF THE PREFERRED EMBODIMENTS

The present invention now will be described more fully hereinafter with reference to the accompanying drawings, in which preferred embodiments of the inventions invention are shown. The present invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

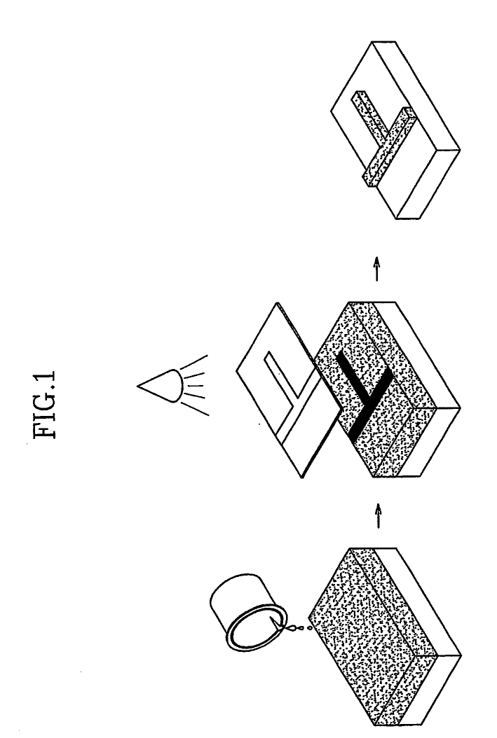

FIG. 1 schematically illustrates a method of forming a metal pattern according to an embodiment of the present invention.

A photosensitive organometallic complex is dissolved in an organic solvent. The dissolved organometallic complex is coated on a target surface to form a photosensitive organometallic layer. The coating is made by way of spin coating or role printing. An example of the photosensitive organometallic complex is a Ag transition compound containing Ag and an ultraviolet sensitive organic ligand. After the coating, the organometallic layer is dried to remove the organic solvent content.

After photo mask with a pattern is placed over the photosensitive organometallic layer, the photosensitive organometallic layer is exposed to light through the photo mask. The light for exposing the organometallic layer of an ultraviolet sensitive Ag transition compound includes ultraviolet. A light-blocking layer of the photo mask is arranged such that an area to be provided with metal is exposed to light while an area to be provided with no metal is not exposed to light-blocking. In the light-exposed area, the organic ligand is vaporized in reaction with the light while leaving only the metal content.

Finally, when the light-exposed organometallic layer is developed using an organic solvent, the organometallic portions containing organic ligand (not exposed to light) are dissolved in the organic solvent to be removed, and the metal portion containing only metal content without organic ligand (exposed to light) is left over to form a metal pattern.

As described above, a metal pattern can be formed by a photolithography process only with the steps of coating, light exposure and development. This simplifies the formation of a metal pattern compared with a conventional art.

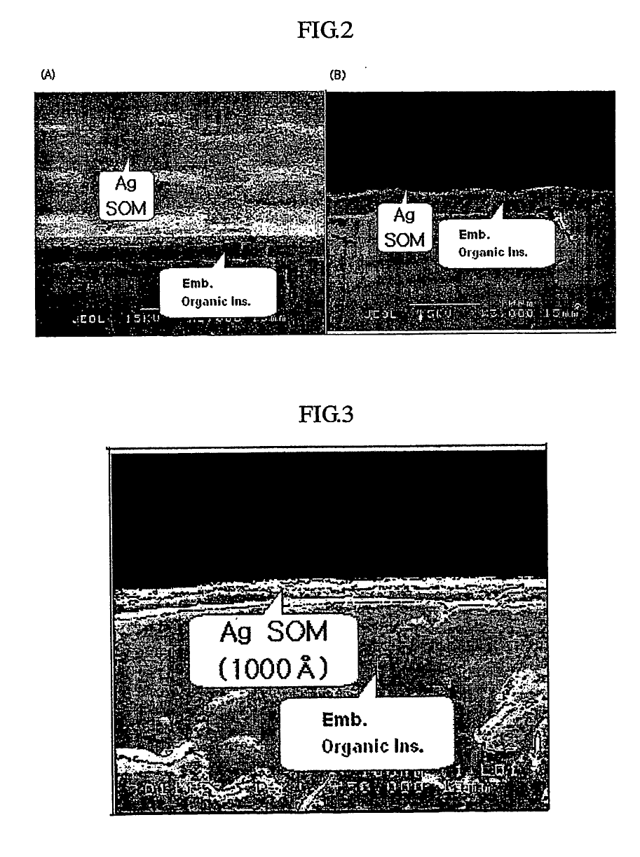

FIG. 2 is SEM photographs showing a surface and a cross section of a metallic thin film manufactured according to an embodiment of the present invention, and FIG. 3 is an enlarged photograph showing a cross section of the metallic thin film shown in FIG. 2B.

FIGS. 2 and 3 illustrate a Ag thin film formed on a surface-embossed (Emb) organic insulating layer by way of a spin on metal (“SOM”) technique according to an embodiment of the present invention. The inventive metallic thin film bears uniformity similar to the metallic thin film formed by sputtering, and hence, can be used as a signal wire or a reflective electrode.

A method of manufacturing a TFT array panel using the metal pattern formation technique will be now described with reference to the appended drawings.

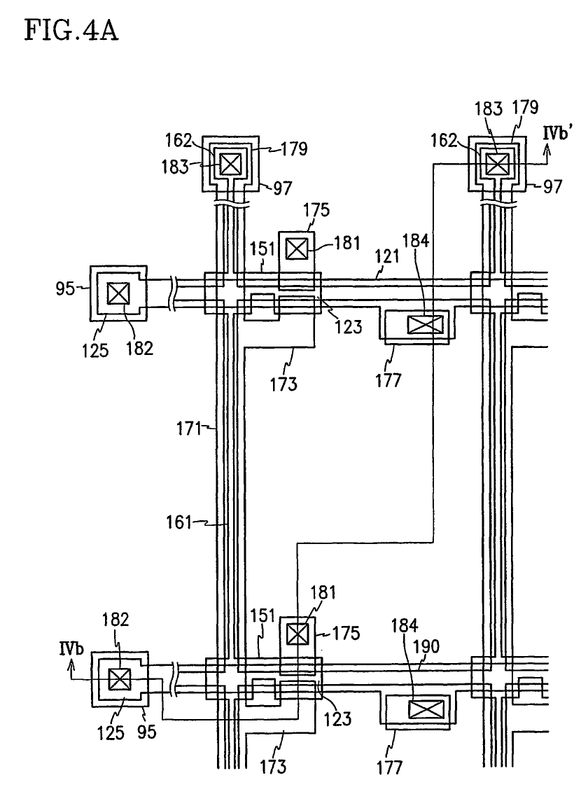

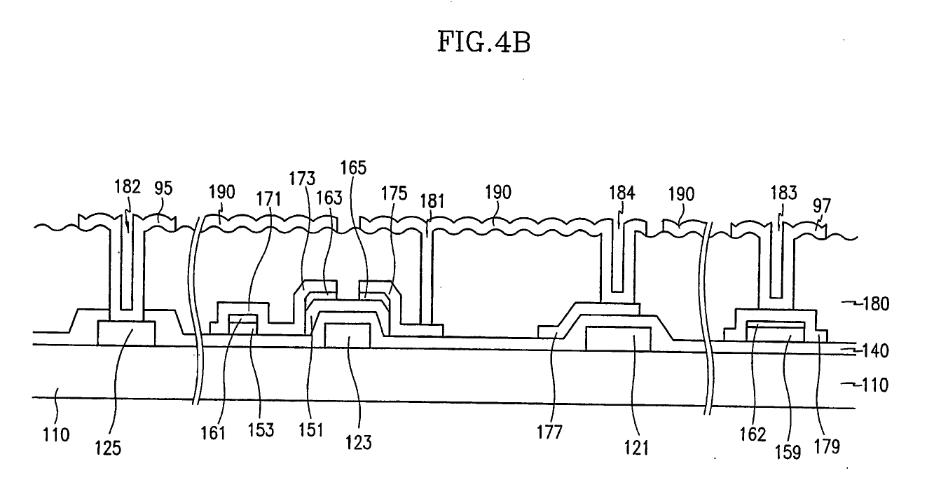

FIG. 4A is a plan view of a TFT array panel according to a first preferred embodiment of the present invention, and FIG. 4B is a cross sectional view of the TFT array panel taken along the IVb-IVb′ line of FIG. 4A.

As shown in FIGS. 4A and 4B, a gate wire 121, 123 and 125 made of Ag is formed on a transparent insulating substrate 110.

The gate wire 121, 123 and 125 includes a plurality of gate lines 121 extending in a transverse direction, a plurality of gate pads 125 connected to one ends of the gate lines 121 to transmit gate signals from an external device to the gate lines 121, and a plurality of gate electrodes 123 connected to the gate lines 121.

A gate insulating layer 140 is formed on the entire surface of the substrate 110 provided with the gate wire 121, 123 and 125.

A semiconductor layer 151, 153 and 159 preferably made of amorphous silicon is formed on the gate insulating layer 140 opposite the gate electrodes 121. An ohmic contact layer 161, 162, 163 and 165 preferably made of amorphous silicon heavily doped with n type impurities is formed on the semiconductor layer 151, 153 and 159.

A data wire 171, 173, 175, 177 and 179 preferably made of Ag is formed on the ohmic contact layer 161, 162, 163 and 165 and the gate insulating layer 140.

The data wire 171, 173, 175, 177 and 179 includes a plurality of data lines 171 perpendicularly intersecting the gate lines 121 to form a plurality of pixels, a plurality of source electrodes 173 branched from the data lines 171 and connected to a portion 163 of the ohmic contact layer, a plurality of data pads 179 connected to one ends of the data lines 171 to receive image signals from an external device, a plurality of drain electrodes 175 formed on the other portion 165 of the ohmic contact layer, located opposite the source electrodes 173 with respect to the gate electrodes 123 and separated from the source electrodes 173, and a plurality of storage capacitor electrodes 177 overlapping the gate lines 121 to enhance the storage capacitance.

A protective layer 180 with embossed surface is formed on the data wire 171, 173, 175, 177 and 179. The protective layer 180 has a plurality of first contact holes 181 exposing the drain electrodes 175, a plurality of second contact holes 182 exposing the gate pads 125, a plurality of third contact holes 183 exposing the data pads 125, and a plurality of fourth contact holes 184 exposing the storage capacitor electrodes 177.

A plurality of reflective electrodes 190, a plurality of subsidiary gate pads 95, and a plurality of subsidiary data pads 97 are formed on the protective layer 180. The reflective electrodes 190 are connected to the drain electrodes 175 and the storage capacitor electrodes 177 through the first and the fourth contact holes 181 and 184. The subsidiary gate pads 95 are connected to the gate pads 125 through the second contact holes 182, and the subsidiary data pads 97 are connected to the data pads 179 through the third contact holes 183. The reflective electrodes 190, the subsidiary gate pads 95 and the subsidiary data pads 97 are preferably made of Ag. The reflective electrodes 190 may be referred to as pixel electrodes in that they generate electric fields together with a common electrode (not shown), but are termed to be reflective in that they reflect the light.

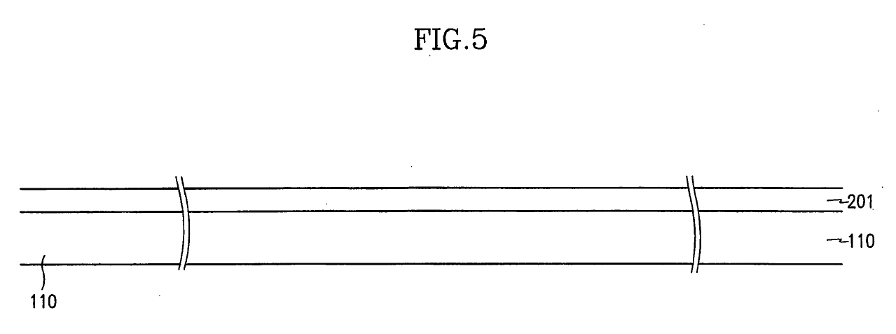

A method of manufacturing a TFT array panel will be now described with reference to FIGS. 5 to 11B.

First, as shown in FIG. 5, an organometallic layer 201 for a gate wire is formed on a transparent insulating substrate 110.

The organometallic layer 201 is formed by dissolving an organometallic complex containing Ag in an organic solvent such that it bears suitable viscosity, coating the solution on the insulating substrate 110, and vaporizing the organic solvent from the solution. The organometallic complex is dissolved in the organic solvent, and leaves Ag after organic ligand is decomposed by light and volatilized.

The coating may be made by way of spin coating or roll printing. The organic solvent is used to facilitate the coating by giving suitable viscosity to the coating solution. The organic solvent is volatilized simultaneously with the coating. Therefore, it is preferable that the coated film have a sufficient thickness in consideration of the volatilization of organic solvent.

The substrate in this embodiment is a transparent insulating substrate for a TFT array panel. However, a semiconductor substrate, a substrate including an insulating layer and underlying wires, or other substrates, where a metallic signal wire will be provided, can be used.

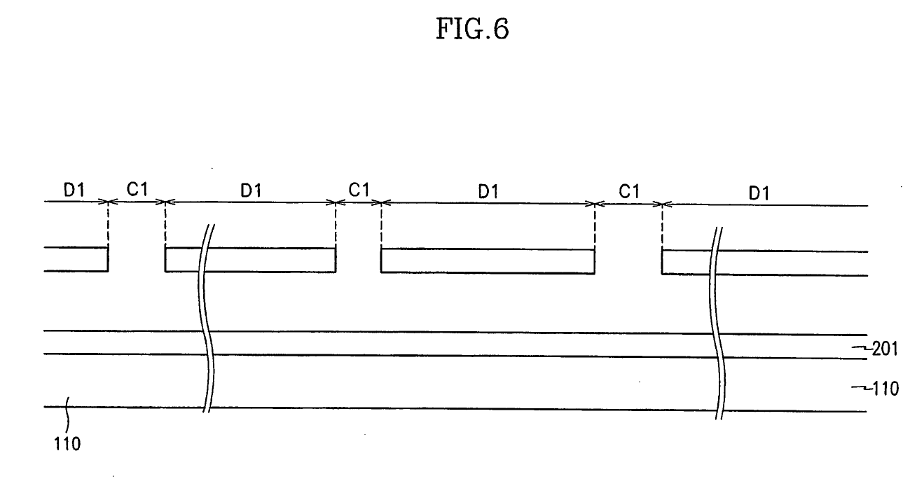

As shown in FIG. 6, a photo mask is placed over the organometallic layer 201 for a gate wire such that predetermined areas of the organometallic layer 201 are exposed (The First Mask). A light-blocking pattern of the photo mask is placed at areas D1 external to wire areas C1 to be provided with a signal wire.

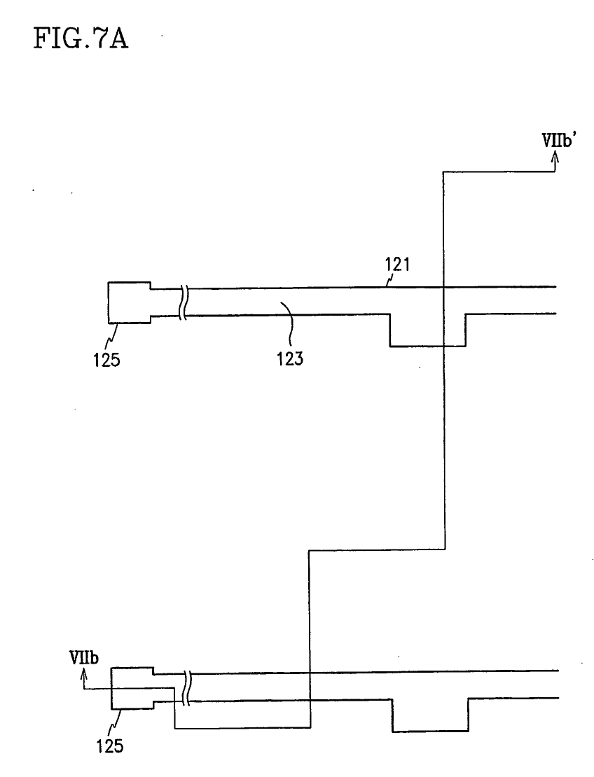

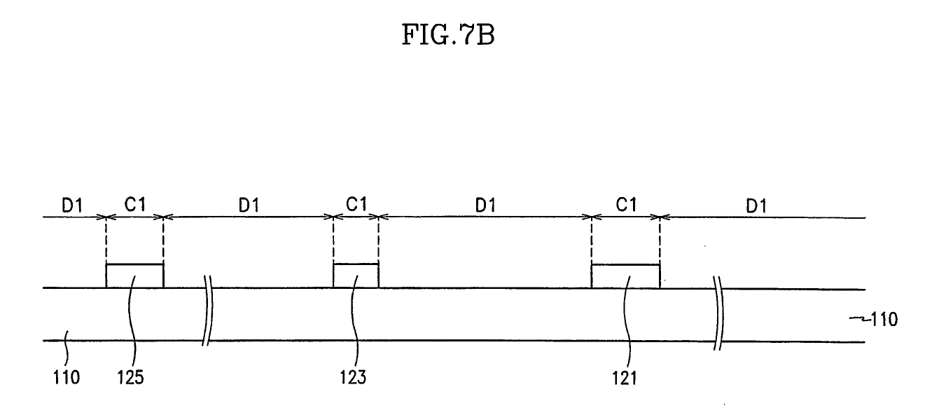

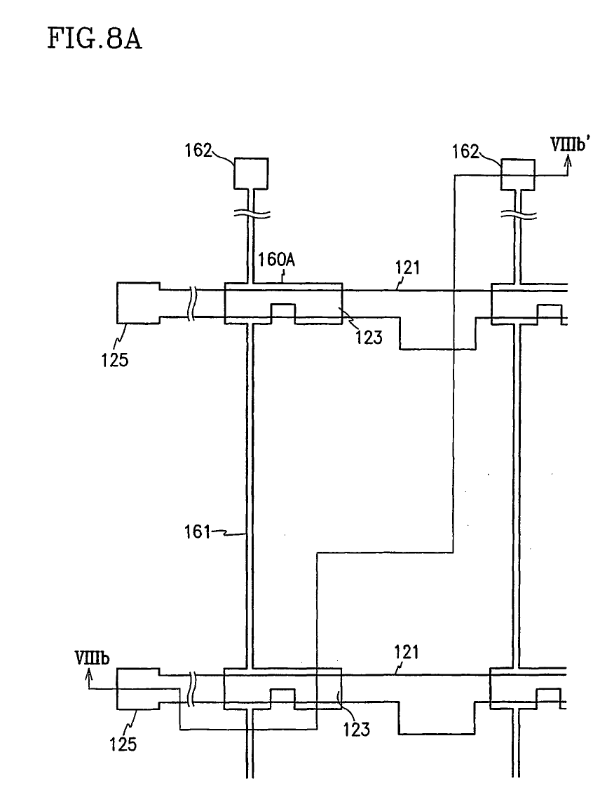

As shown in FIGS. 7A and 7B, the organometallic layer 201 is exposed to light and developed to form a gate wire 121, 123 and 125.

When exposed to light, the portion of the organometallic layer 201 on the areas C1 with no light-blocking pattern is optically decomposed so that the organic ligand thereof is volatilized while leaving the Ag content there. As the portion of the organometallic layer 201 on the areas D1 with the light-blocking pattern is not optically decomposed, it is removed using an organic solvent. Consequently, a gate wire 121, 123 and 125 made of silver is formed on the insulating substrate 110.

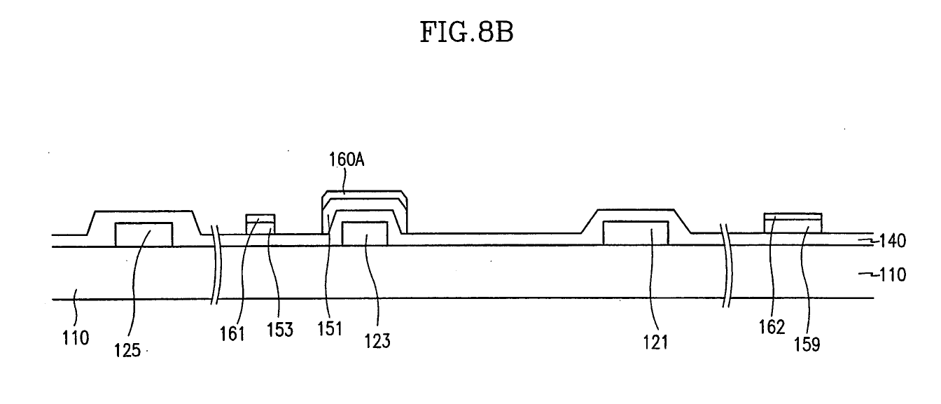

As shown in FIGS. 8A and 8B, silicon nitride or silicon oxide is deposited on the substrate provided with the gate wire 121, 123 and 125 to form a gate insulating layer 140.

An undoped amorphous silicon layer and a doped amorphous silicon layer heavily doped with n-type impurity are sequentially formed on the gate insulating layer 140. The doped amorphous silicon layer and the undoped amorphous silicon layer are sequentially etched by photolithography, thereby forming a semiconductor layer 151, 153 and 159, and an ohmic contact layer 160A, 161 and 162 on the gate insulating layer 140 opposite the gate electrodes 123 (The Second Mask).

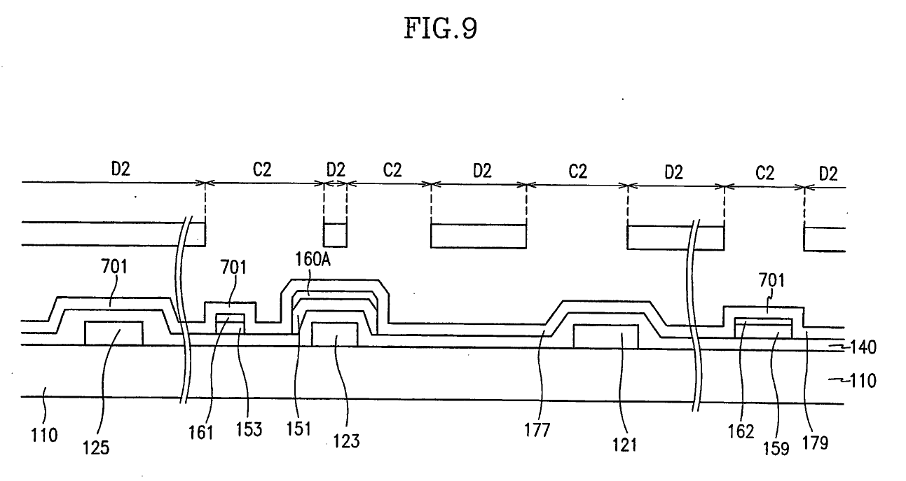

As shown in FIG. 9, an organic metallic layer 701 for a data wire is formed on the ohmic contact layer 160A, 161 and 162, and a photo mask is positioned over target wire areas C2 (The Third Mask).

The process of forming an organometallic layer 701 for a data wire and a light-blocking pattern is substantially the same as the process of forming the gate wire 121, 123 and 125. The light-blocking pattern of the photo mask is positioned at areas D2 where a data wire 171, 173, 175 and 179 and storage capacitor electrodes 177 are not formed.

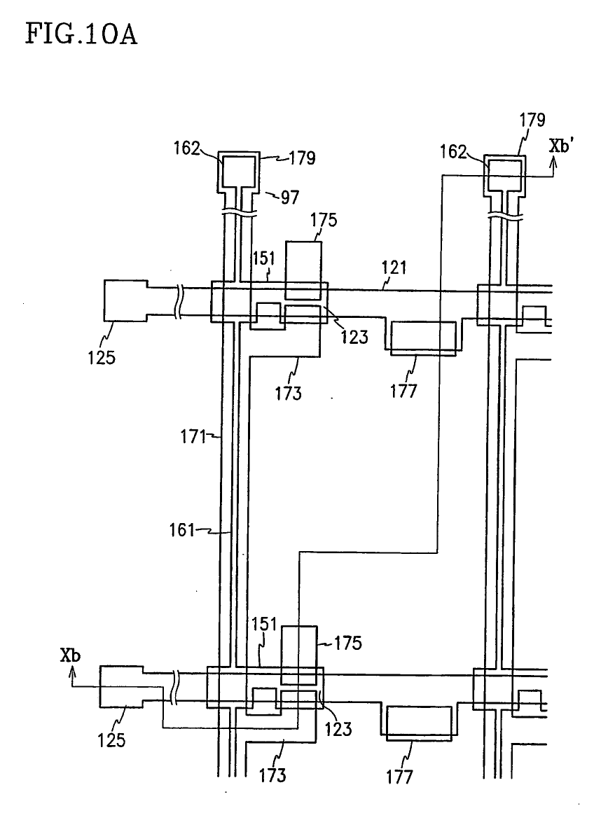

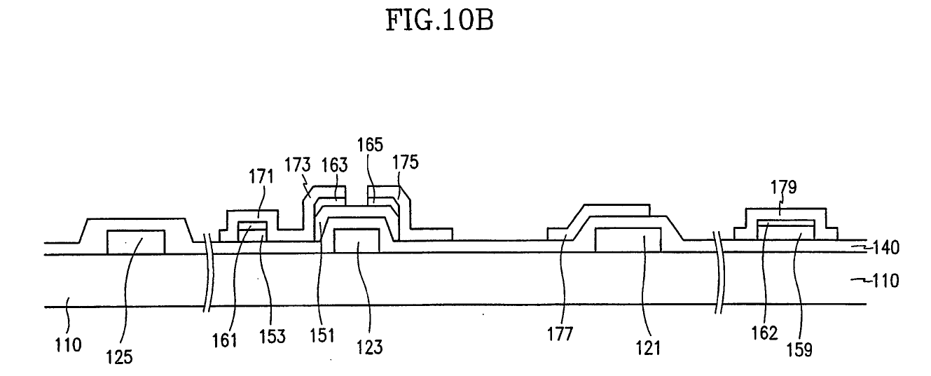

As shown in FIGS. 10A and 10B, a data wire and a plurality of storage capacitor electrodes 171, 173, 175, 177 and 179 are formed by light exposure and development. The portions 160A of the ohmic contact layer 160A under the source and the drain electrodes 173 and 175 are etched using the source and the drain electrodes 173 and 175 as a mask such that each of the portions 160A is separated into several portions, thereby completing the ohmic contact pattern 161, 162, 163 and 165.

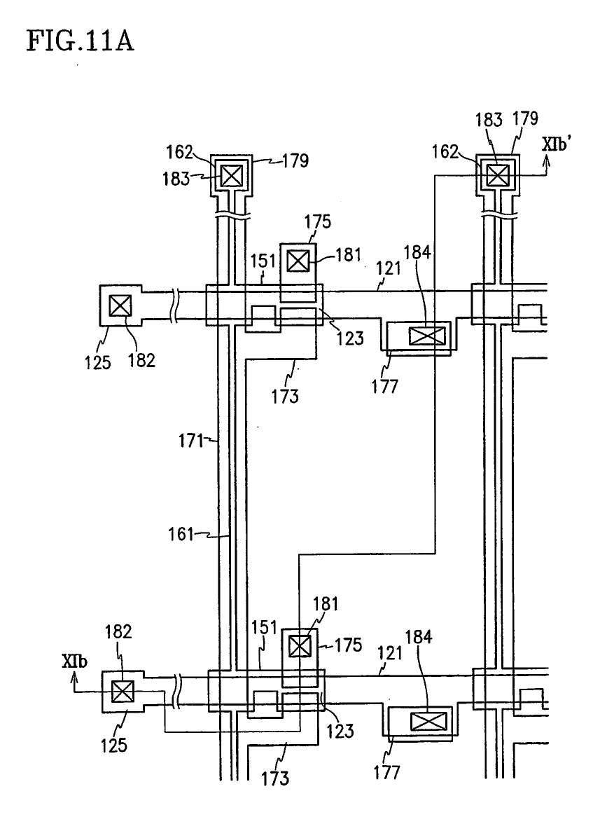

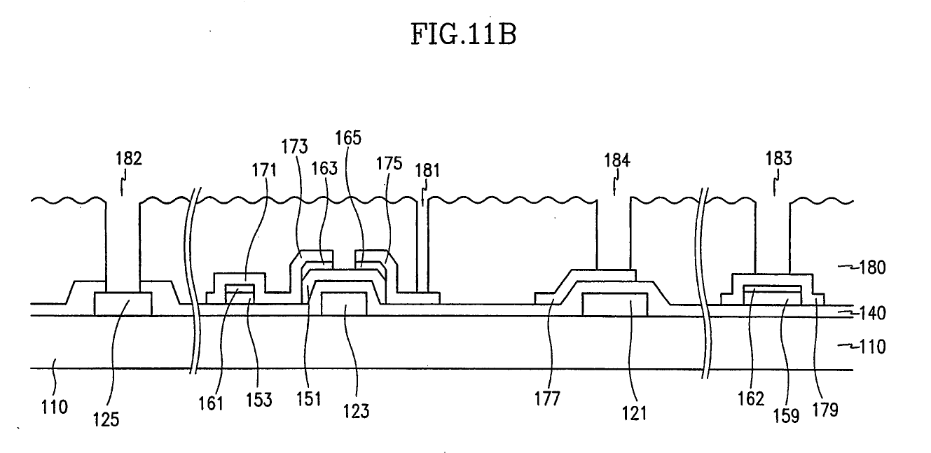

As shown in FIGS. 11A and 11B, an insulating material is deposited on the data wire 171, 173, 175, 177 and 179 to form a protective layer 180. The protective layer 180 is photo-etched to form a plurality of first to fourth contact holes 181 to 184. In order to emboss the surface of the protective layer 180, a photoresist film having a portion with zero thickness, a portion with a small thickness and a portion with a large thickness can be used. The portion with zero thickness is placed at areas to be provided with the contact holes 181 to 185, the portion with a small thickness is placed at areas to be provided with depressions, and the portion with a large thickness is placed at areas to be provided with prominences. Furthermore, the protective layer 180 may be made of a photosensitive organic material, which can be processed only by photolithography (The Fourth Mask).

Thereafter, an organic metallic layer is deposited on the substrate with the first to the fourth contact holes 181 to 184, exposed to light, and developed to form a plurality of reflective electrodes 190, a plurality of subsidiary gate pads 95, and a plurality of subsidiary data pads 97 (The Fifth Mask).

The process of forming the reflective electrodes 190, the subsidiary gate pads 95 and the subsidiary data pads 97 is substantially the same as the process of forming the gate wire and the data wire.

As described above, among the five photolithography steps, three steps are solely used without etching, thereby simplifying the method of manufacturing the TFT array panel and reducing the production cost.

### Second Embodiment

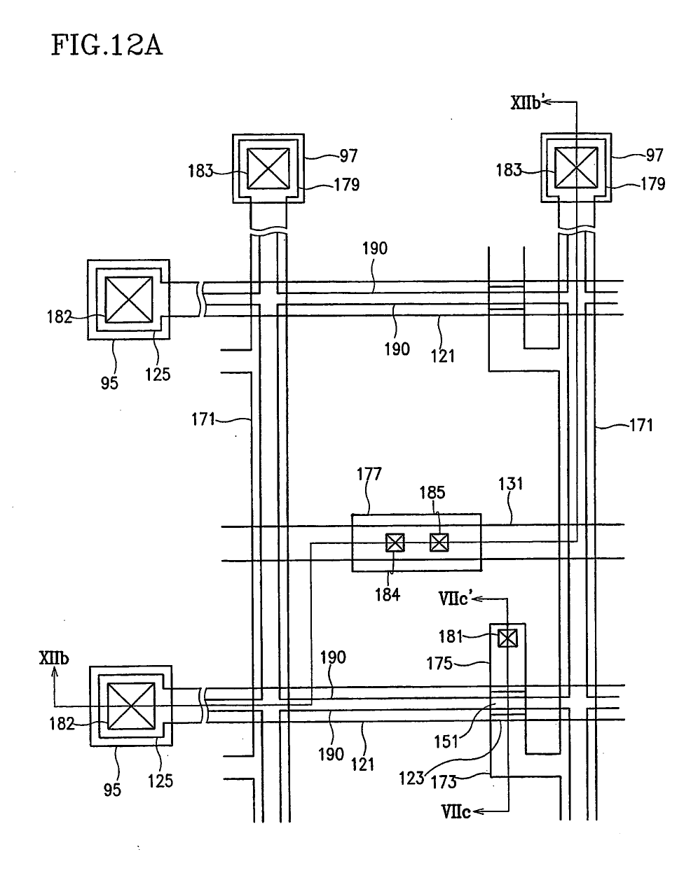

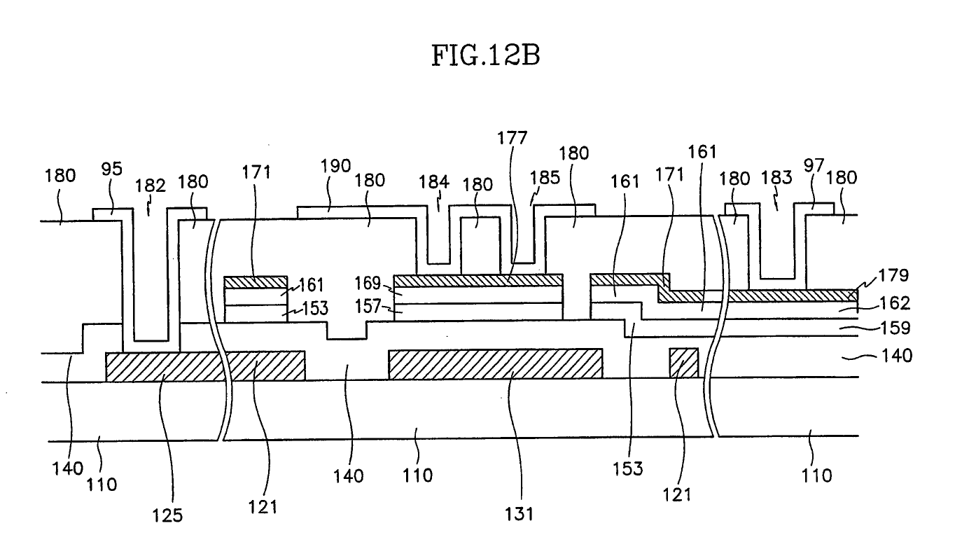

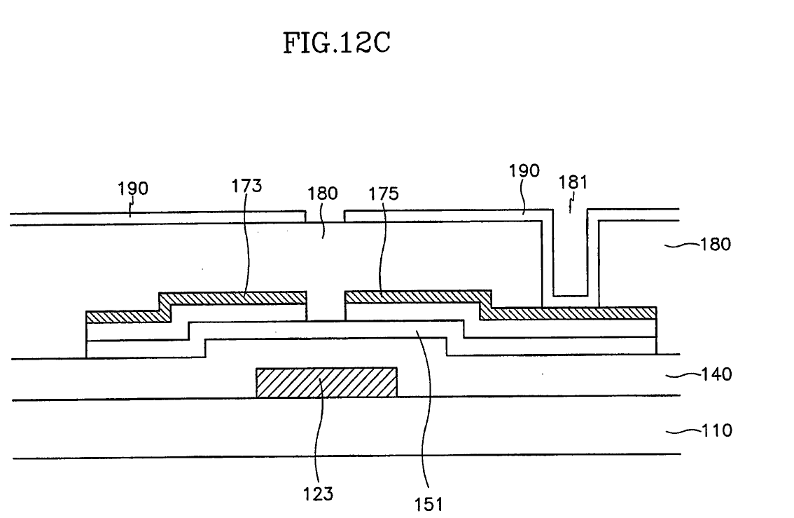

FIG. 12A is a layout view of a TFT array panel according to a second embodiment of the present invention, and FIGS. 12B and 12C are cross sectional views of the TFT array panel shown in FIG. 12A taken along the lines XIIIb-XIIIb′ and XIIIc-XIIIc′, respectively.

As shown in FIGS. 12A to 12C, a gate wire 121, 123 and 125 made of Ag is formed on a transparent insulating substrate 110 with silver.

The gate wire includes a plurality of gate lines 121, a plurality of gate pads 125, and a plurality of gate electrodes 123. The gate wire may further include a plurality of storage electrode lines 131. The storage electrode lines 121 overlap storage capacitor conductors connected to pixel electrodes to form storage capacitors for enhancing the charge storing capacity of the pixels, which is described later. In case the overlapping of the pixel electrodes and the gate lines gives sufficient storage capacitance, the storage electrode lines 131 may be omitted.

A gate insulating layer 140 is formed on the gate wire 121, 123 and 125 and the storage electrode lines 131. An amorphous silicon layer 151, 153 and 159 and an ohmic contact layer 161, 162, 163, 165 and 169 are formed on the predetermined areas of the gate insulating layer 140.

A data wire 171, 173, 175 and 179 made of Ag is formed on the ohmic contact layer 161, 162, 163 and 165. The data wire 171, 173, 175 and 179 includes a plurality of data lines 171, a plurality of data pads 179, a plurality of source electrodes 173, and a plurality of drain electrodes 175. In the existence of the storage electrode lines 131, an amorphous silicon layer 157, an ohmic contact layer 169 and a plurality of storage capacitor electrodes 177 are formed on the storage electrode lines 131.

The data wire 171, 173, 175 and 179, the storage capacitor electrodes 177, and the ohmic contact layer 161, 162, 163, 165 and 169 have substantially the same planar pattern. The amorphous sflicon layer 151, 153, 157 and 159 has substantially the same plane pattern as the ohmic contact layer 161, 162, 163, 165 and 169 except for channel portions 151 of the TFTs. That is, the source and the drain electrodes 173 and 175 are separated from each other, and the portions of the ohmic contact layer portions 163 and 165 placed under the source and the drain electrodes 173 and 175 are also separated from each other. However, the amorphous layer 151 continue to proceed there without disconnection to form TFT channels.

A protective layer 180 with a plurality of first to fifth contact holes 181 to 185 is formed on the data wire 171, 173, 175 and 179 and the storage capacitor electrodes 177. The first contact holes 181 expose the drain electrodes 175, the second contact holes 182 expose the gate pads 125, the third contact hole 183 exposes the data pads 179, and the fourth and the fifth contact holes 184 and 185 expose the storage capacitor electrodes 179. The protective layer 180 has an embossed surface.

A plurality of reflective electrodes 190, a plurality of subsidiary gate pads 95 and a plurality of subsidiary data pads 97 are formed on the protective layer 180. The reflective electrodes 190 are connected to the drain electrodes 175 through the first contact holes 181 while being connected to the storage capacitor electrodes 177 through the fourth and the fifth contact holes 184 and 185. The subsidiary gate pads 95 are connected to the gate pads 125 through the second contact holes 182. The subsidiary data pads 97 are connected to the data pads 179 through the third contact holes 183.

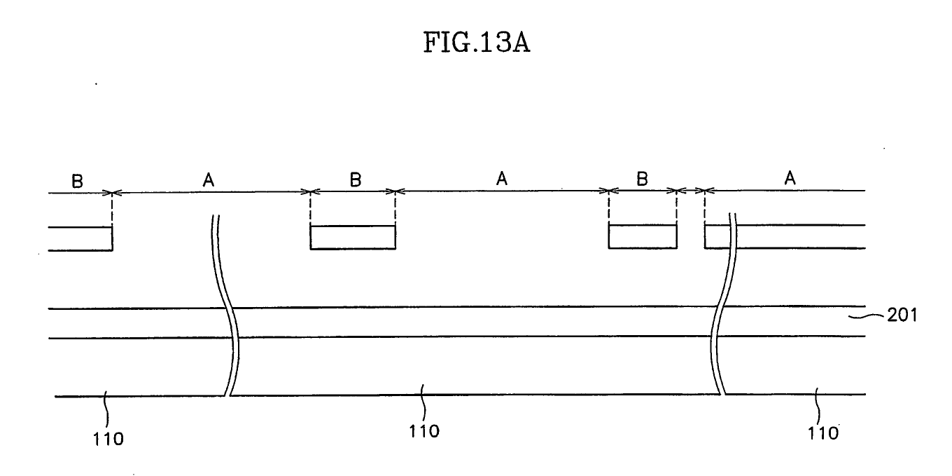

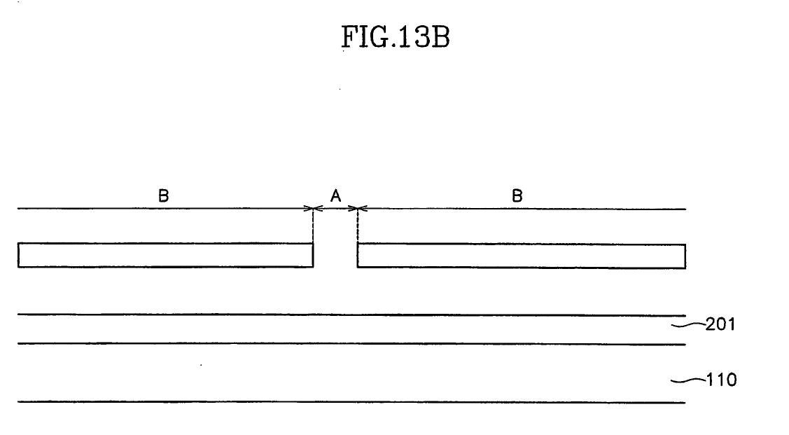

A method of manufacturing a TFT array panel will be now described with reference to FIGS. 13 to 18C.

As shown in FIGS. 13A and 13B, an organometallic layer 201 for a gate wire is formed on a transparent insulating substrate 110, and a photo mask is placed over the organometallic layer 201 such that predetermined areas of the organometallic layer 201 are exposed (The First Mask).

The organometallic layer 201 is formed by dissolving a photosensitive organometallic complex containing Ag in an organic solvent such that it bears suitable viscosity and coating the solution on the insulating substrate 110.

The coating may be made by way of spin coating or roll printing. The organic solvent is used to facilitate the coating by giving suitable viscosity to the coating solution. The organic solvent is volatilized simultaneously with the coating. Therefore, it is preferable that the coated film have a sufficient thickness in consideration of the volatilization of organic solvent. A light-blocking pattern of the photo mask is placed at areas D1 external to wire areas C1 to be provided with a signal wire.

The substrate is a transparent insulating substrate for a TFT array panel. However, a semiconductor substrate, a substrate including an insulating layer and underlying wires, or other substrates, where a metallic signal wire will be provided, can be used.

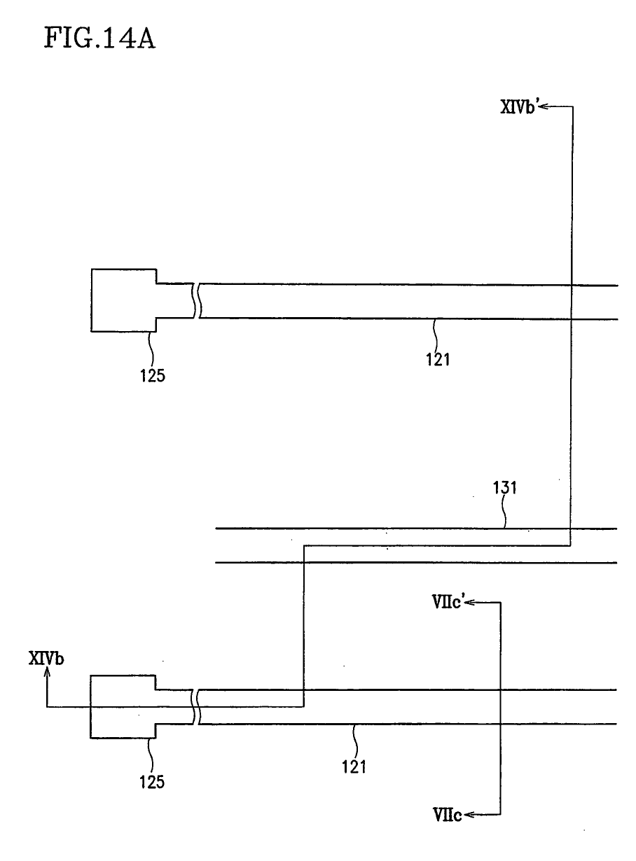

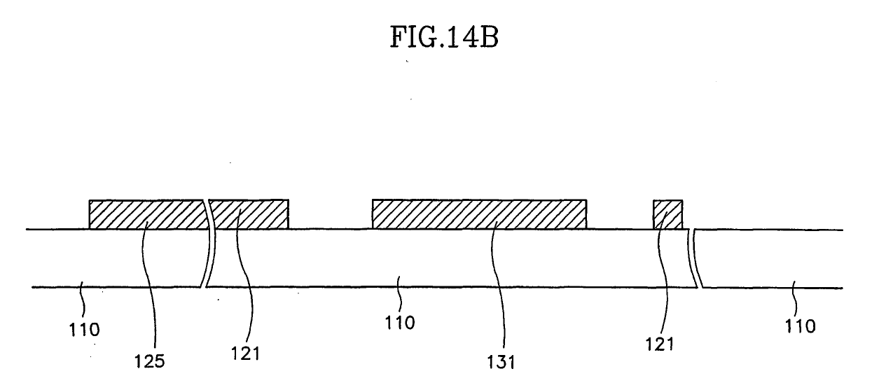

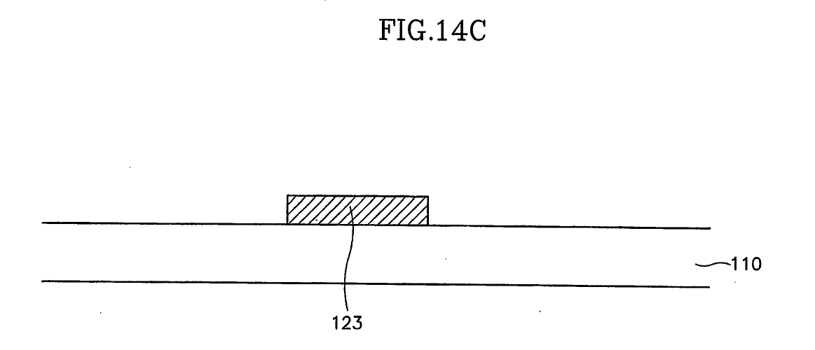

As shown in FIGS. 14A and 14C, the substrate is exposed to light and developed to form a gate wire 121, 123 and 125.

When exposed to light, the portion of the organometallic layer 201 on the areas C1 with no light-blocking pattern is optically decomposed so that the organic ligand thereof is volatilized while leaving the Ag content there. As the portion of the organometallic layer 201 on the areas D1 with the light-blocking pattern is not optically decomposed, it is removed using an organic solvent. Consequently, a gate wire 121, 123 and 125 made of silver is formed on the insulating substrate 110.

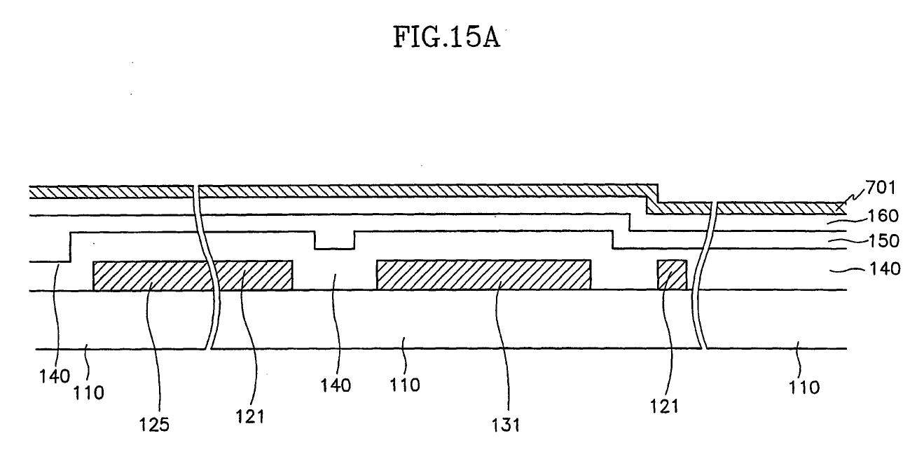

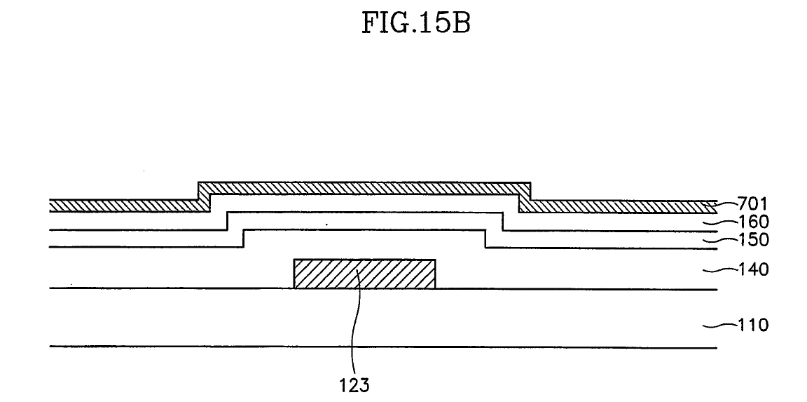

As shown in FIGS. 15A and 15B, a gate insulating layer 140 preferably made of silicon nitride, an undoped amorphous silicon layer 150, and an doped amorphous silicon layer 160 doped with impurity are sequentially deposited by chemical vapor deposition (“CVD”) on the gate wire 121, 123 and 125 and the storage electrode lines 131. A metallic layer 701 is formed on the doped amorphous silicon layer 160.

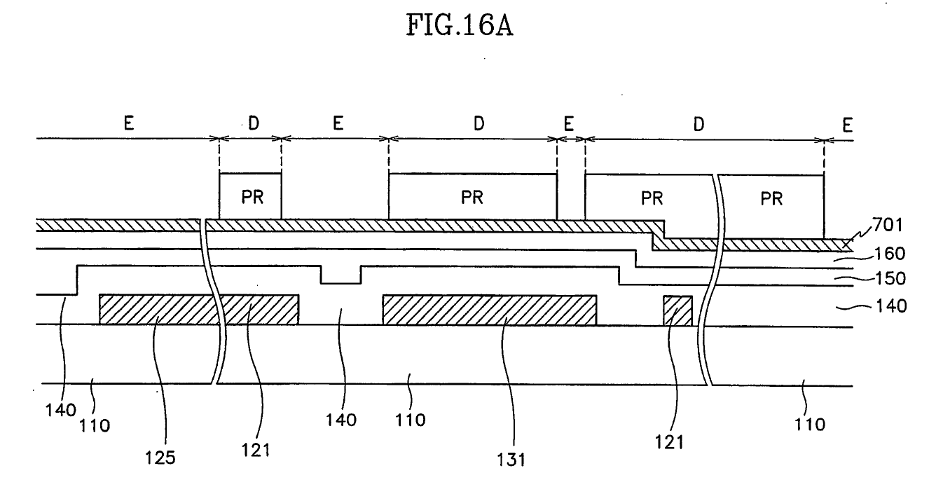

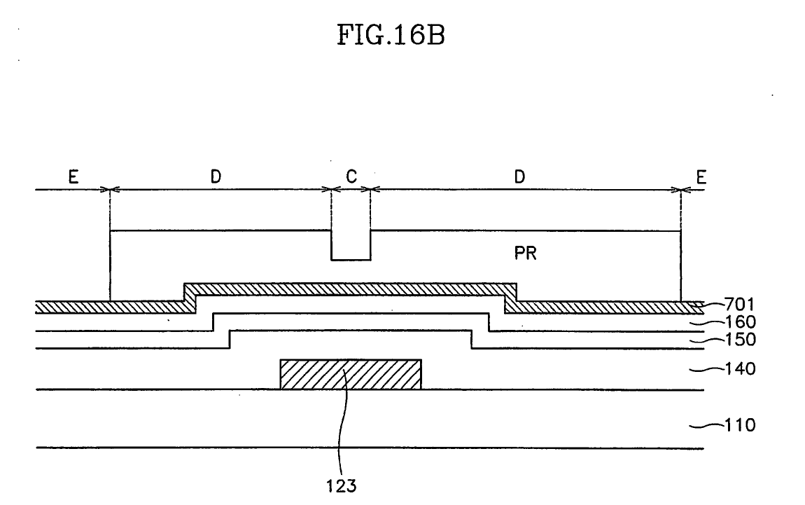

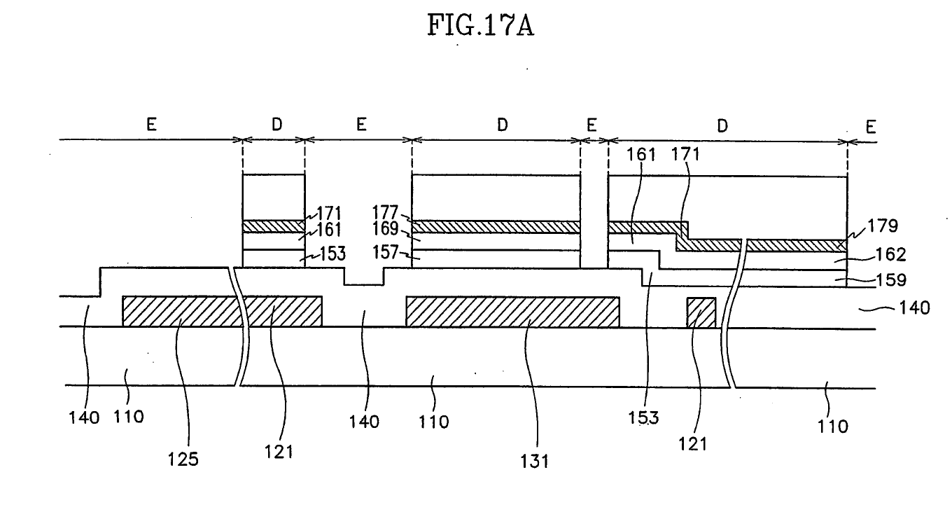

As shown in FIGS. 16A and 16B, a photoresist film is coated on the metallic layer 701A, exposed to light, and developed to form a photoresist pattern PR. The photoresist pattern PR has first to third portions C, D and E. The first portion C is placed on the area where a channel of the TFT is formed, and the second portion D is placed on the area where the data wire is formed. The first portion C has a thickness smaller than the second photoresist pattern portion D. The third portion E bears no thickness to expose the metallic layer 701.

The position-dependent thickness of the photoresist film can be obtained by a slit pattern, a lattice pattern, or a semitransparent film.

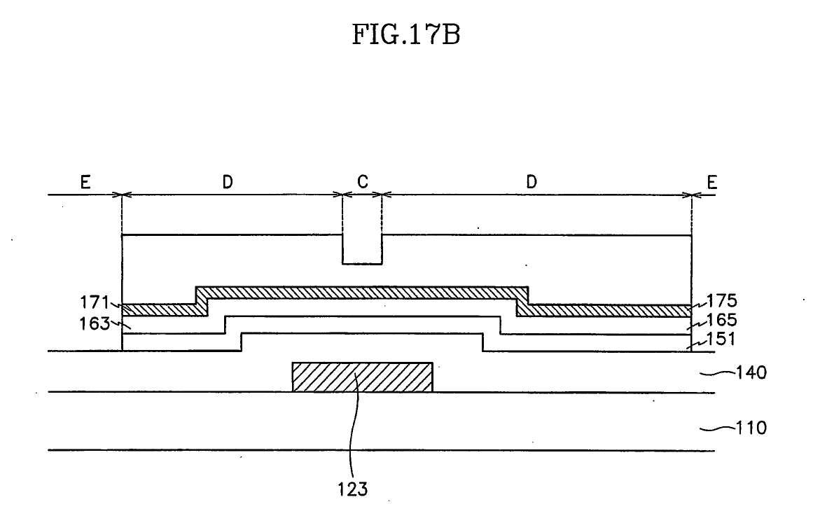

As shown in FIGS. 17A and 17B, with the use of the photoresist pattern PR as a mask, the metallic layer 701, the doped amorphous silicon layer 160 and the amorphous silicon layer 150 are sequentially etched to form a data wire 701A, 171, 175 and 179, a plurality of storage capacitor electrodes 177, an ohmic contact layer 160A, 161, 162 and 169, and an amorphous silicon layer 151, 153, 157 and 159. The data wire and the ohmic contact layer are not yet completed in that the portions for the source and the drain electrodes 701A and the underlying ohmic contact layer 160A proceed without separation.

Specifically speaking, the etching by the use of the photoresist pattern as a mask is made by multi-steps.

First, dry etching is made on the area of the third portion E such that the doped amorphous silicon layer 160 is exposed.

Thereafter, portions of the doped amorphous silicon layer 160 and the amorphous silicon layer 150 on the area without photoresist are dry-etched together with the first portion C, thereby completing the amorphous silicon layer 151, 153, 157 and 159. At this time, the first portion C is etched to expose the underlying metallic layer.

Thereafter, the first portion C is completely removed by ashing to entirely exposing the metallic layer on the channel area. At this time, the second portion D is partially etched.

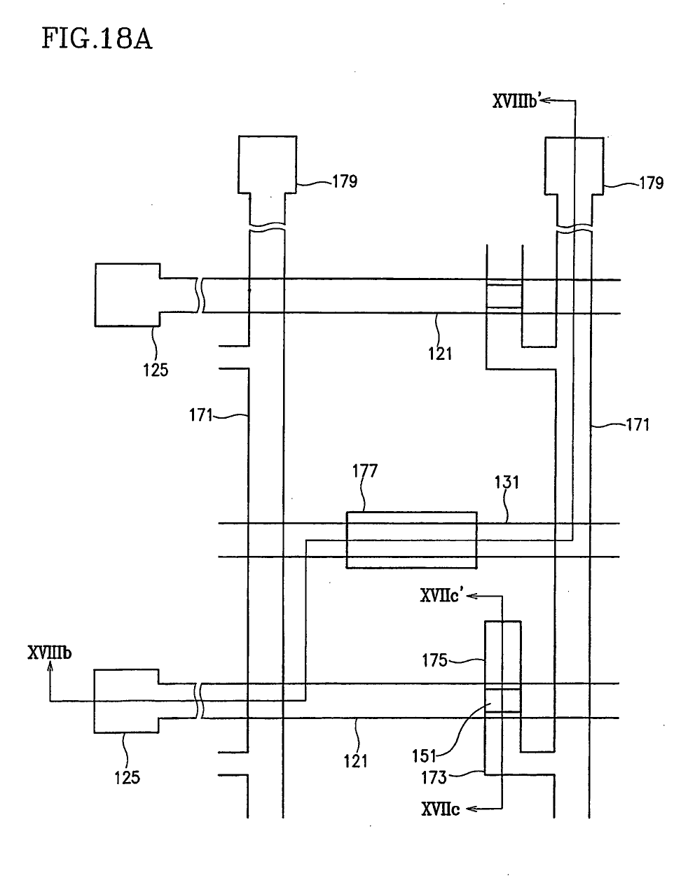

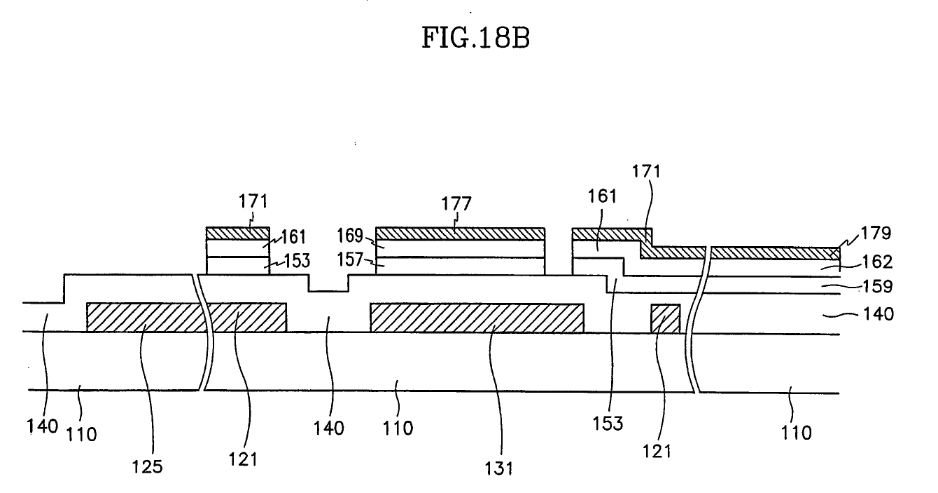

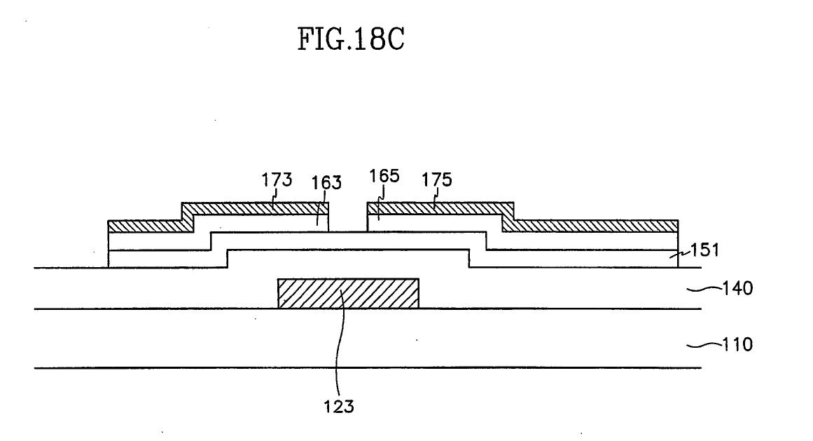

As shown in FIGS. 18A to 18C, portions of the exposed metallic layer and the doped amorphous silicon layer at the first portion C are etched to complete a data wire 171, 173, 175 and 179, and an ohmic contact layer 161, 162, 163, 165 and 169. At this time, the amorphous silicon layer 151 at the first portion C may be partially etched.

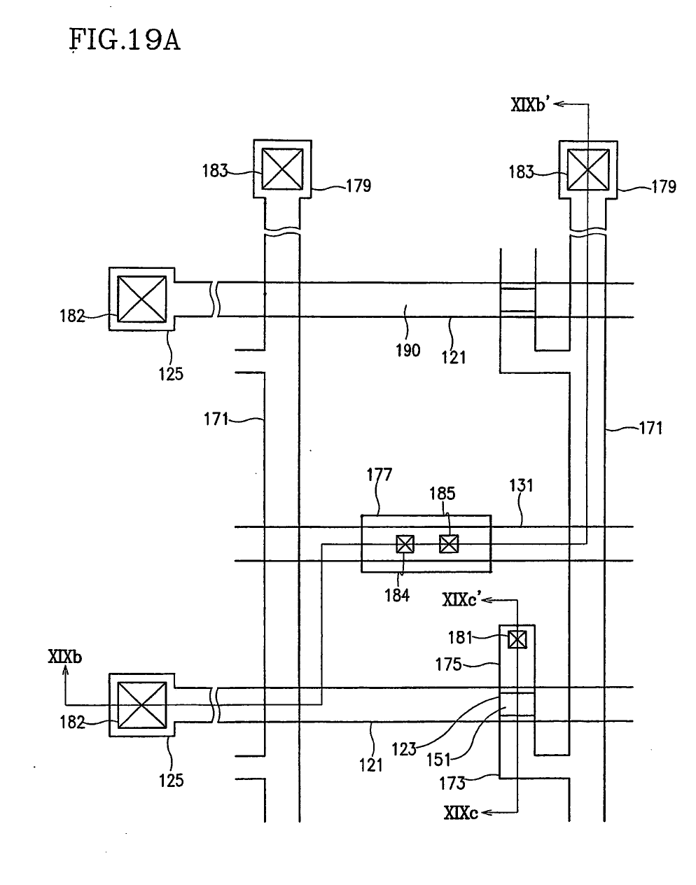

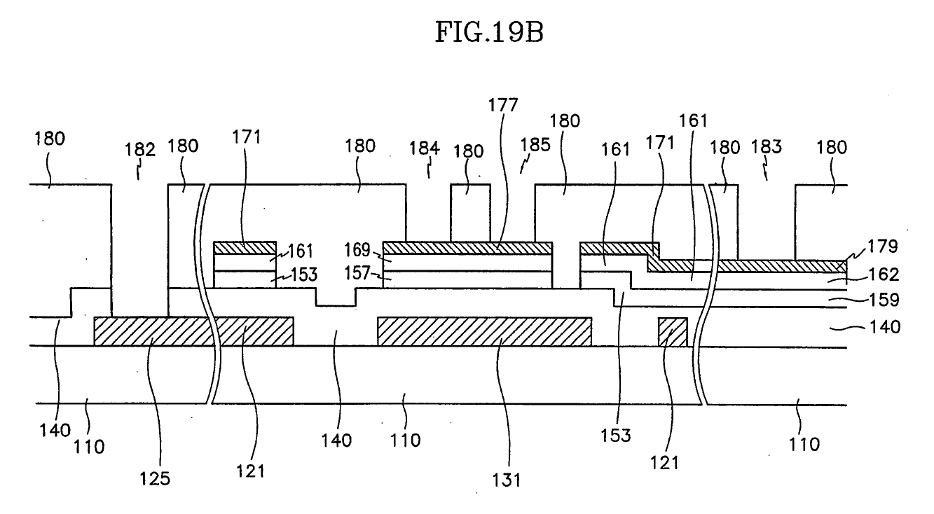

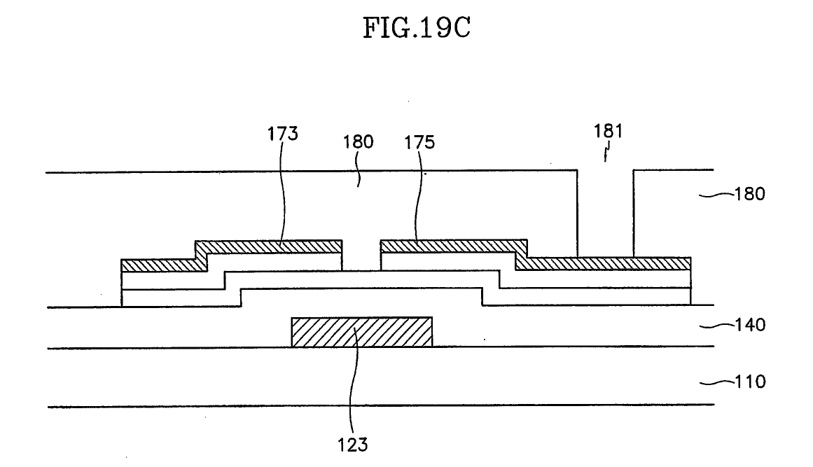

As shown in FIGS. 19A to 19C, a protective layer 180 is formed on the data wire 171, 173, 175 and 179 and the storage capacitor electrodes 177, and photo-etched patterned to form a plurality of first to fifth contact holes 181 to 185. In order to emboss the surface of the protective layer 180, a photoresist film having a portion with zero thickness, a portion with a small thickness and a portion with a large thickness can be used. The portion with zero thickness is placed at areas to be provided with the contact holes 181 to 185, the portion with a small thickness is placed at areas to be provided with depressions, and the portion with a large thickness is placed at areas to be provided with prominences. Furthermore, the protective layer 180 may be made of a photosensitive organic material, which can be processed only by photolithography (The Third Mask).

Thereafter, an organic metallic layer is deposited on the substrate with the first to the fourth contact holes 181 to 184, exposed to light, and developed to form a plurality of reflective electrodes 190, a plurality of subsidiary gate pads 95, and a plurality of subsidiary data pads 97 (The Fourth Mask).

The process of forming the reflective electrodes 190, the subsidiary gate pads 95 and the subsidiary data pads 97 is substantially the same as the process of forming the gate wire and the data wire.

The reflective electrode 190 is connected to the drain electrode 175 and the storage capacitor electrode 177 through the fist, the fourth and the fifth contact holes 181, 184 and 185. The subsidiary gate pad 95 is connected to the gate pad 125 through the second contact hole 182. The subsidiary data pad 97 is connected to the data pad 179 through the third contact hole 183 (as shown in FIGS. 12B and 12C).

In relation to the first and the second embodiments, Ag is used to form a signal wire and a reflective electrode, but other metals such as aluminum may be used for that purpose.

As described above, a photosensitive organometallic complex is coated on the target object, exposed to light, and developed to form a metal pattern. In this way, the processing steps can be simplified.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A method of forming a metal pattern, the method comprising:
forming an organometallic layer by coating a photosensitive organometallic complex;
exposing the organometallic layer to light through a photo mask; and
forming a metal pattern by developing the organometallic layer.

2. The method of claim 1 wherein the development of the organometallic layer is made by way of an organic solvent.

3. The method of claim 1 wherein the light-blocking pattern of the photo mask is positioned at the area external to the area to be provided with the metal pattern.

4. A method of manufacturing a thin film transistor array panel, the method comprising:
forming a gate wire on an insulating substrate, the gate wire including a gate line, a gate electrode and a gate pad;
sequentially depositing a gate insulating layer, an amorphous silicon layer and an ohmic contact layer on the gate wire;
patterning the ohmic contact layer and the amorphous silicon layer by photolithography;
forming a data wire on the ohmic contact layer, the data wire including source and drain electrodes, a data line and a data pad;
forming a protective layer on the data wire, the protective layer having a first contact hole exposing the drain electrode, a second contact hole exposing the gate pad and a third contact hole exposing the data pad; and
forming a pixel electrode, a subsidiary gate pad and a subsidiary data pad on the protective layer, the pixel electrode being connected to the drain electrode through the first contact hole, the subsidiary gate pad being connected to the gate pad through the second contact hole, the subsidiary data pad being connected to the data pad through the third contact hole;
wherein at least one of the formations of the gate wire, the data wire and the pixel electrode comprises:
forming an organometallic layer by coating a photosensitive organometallic complex;
placing a photo mask over the organometallic layer such that a predetermined region of the organometallic layer is exposed;
exposing the organometallic layer to light through a photo mask; and
developing the organometallic layer.

5. A method of manufacturing a thin film transistor array panel, the method comprising the steps of:
forming a gate wire on an insulating substrate, the gate wire having gate lines, gate electrodes and gate pads;
sequentially depositing a gate insulating layer, an amorphous silicon layer, an ohmic contact layer and a metallic layer on the gate wire;
patterning the metallic layer, the ohmic contact layer and the amorphous silicon layer by photolithography to form a data wire and channel portions, the data wire having source and drain electrodes, data lines and data pads, the channel portions being placed between the source and the drain electrodes;
forming a protective layer on the data wire, the protective layer having first to third contact holes; and
forming a pixel electrode, a subsidiary gate pad and a subsidiary data pad on the protective layer, the pixel electrode being connected to the drain electrode through the first contact hole, the subsidiary gate pad being connected to the gate pad through the second contact hole, the subsidiary data pad being connected to the data pad through the third contact hole;
wherein at least one of the steps of forming the gate wire, the data wire and the pixel electrode comprises the sub-steps of:
forming an organometallic layer by coating a photosensitive organometallic complex;
placing a photo mask over the organometallic layer such that a predetermined region of the organometallic layer is exposed to the outside;
exposing the organometallic layer to light by the photo mask; and
developing the organometallic layer.

6. The method of claim 4 or 5 wherein the development of the organometallic layer is made by way of an organic solvent.

7. The method of claim 4 or 5 wherein the light-blocking pattern of the photo mask is positioned at the area external to the area to be made of the signal wire or the pixel electrode.

8. The method of claim 4 or 5 wherein the metal is Ag.

9. The method of claim 4 or 5 wherein the protective layer has a surface with prominent and depressed portions.

10. A thin film transistor array panel comprising:
an insulating substrate;
a gate wire formed on the insulating substrate;
a gate insulating layer formed on the gate wire;
a semiconductor layer formed on the gate insulating layer;
a data wire formed on the semiconductor layer and the gate insulating layer;
a protective layer formed on the data wire; and
a pixel electrode formed on the protective layer;
wherein at least one of the gate wire, the data wire and the pixel electrode is formed by way of a metal pattern formation process comprising the steps of:
forming an organometallic layer by coating a photosensitive organometallic complex;
placing a photo mask over the organometallic layer such that a predetermined region of the organometallic layer is exposed to the outside;
exposing the organometallic layer to light through the photo mask; and
developing the organometallic layer.

11. The thin film transistor array panel of claim 10 wherein the semiconductor layer comprises an amorphous silicon layer and an ohmic contact layer, the ohmic contact layer has the same plane pattern as the data wire, and the amorphous silicon layer has the same plane pattern as the ohmic contact layer at the non-channel area.

12. A thin film transistor array panel comprising:
an insulating substrate;
a gate wire formed on the insulating substrate;
a gate insulating layer formed on the gate wire;
a data wire formed on the gate insulating layer with a triple-layered structure of an amorphous silicon layer, an ohmic contact layer and a metallic layer;
a protective layer formed on the data wire; and
a pixel electrode formed on the protective layer;
wherein at least one of the gate wire, the data wire and the pixel electrode is formed by way of a metal pattern formation process comprising the steps of:
forming an organometallic layer by coating a photosensitive organometallic complex;
placing a photo mask over the organometallic layer such that a predetermined region of the organometallic layer is exposed to the outside;
exposing the organometallic layer to light through the photo mask; and
developing the organometallic layer.

13. The thin film transistor array panel of claim 12 wherein the data wire has data lines, source electrodes connected to the data lines and drain electrodes facing the source electrodes, and a channel portion is formed between the source and the drain electrodes only with an amorphous silicon layer.
